(19) United States
(12) Patent Application Publication
(10) Pub. No.: US 2022/0333233 A1
(43) Pub. Date: Oct. 20, 2022

(54) OPTICAL THIN FILMS AND FABRICATION THEREOF

(71) Applicant: University of Southampton, Southampton, Hampshire (GB)

(72) Inventors: Kai SUN, Southampton, Hampshire (GB); Cornelis Hendrik DE GROOT, Southampton, Hampshire (GB); Otto Lambert MUSKENS, Southampton, Hampshire (GB)

(21) Appl. No.: 17/761,110

(22) PCT Filed: Sep. 11, 2020
(86) PCT No.: PCT/GB2020/052197

§ 371 Date: Mar. 16, 2022

(30) Foreign Application Priority Data
Sep. 19, 2019 (GB) 1913533.4

(51) Int. Cl. C23C 16/04; G02B 5/08; C23C 16/40; C23C 16/50

(52) U.S. Cl. CPC C23C 16/042; G02B 5/0816; C23C 16/407; C23C 16/50

(57) ABSTRACT

A method of forming an optical thin film, comprises providing an assembly comprising a layer of semiconductor material deposited on a substrate, the semiconductor material comprising a compound of at least one metal and a group VI element; depositing a masking layer onto the layer of semiconductor material, the masking layer being patterned to expose one or more regions of the layer of semiconductor material; applying to the assembly a plasma of the group VI element in order to cause indiffusion of the group VI element into the semiconductor material in the exposed regions while the masking layer blocks indiffusion in unexposed regions, the indiffusion causing a reduction in carrier density in the semiconductor material; and removing the masking layer; thereby forming, from the layer of semiconductor material, an optical thin film having a variation in carrier density and corresponding variation in optical properties matching the patterning of the masking layer in a plane parallel to the substrate.

### BACKGROUND OF THE INVENTION

The present invention relates to optical thin films and techniques for the fabrication of optical thin films.

Optical thin films can be formed from a layer of semiconductor material, in which optical properties such as the refractive index and the absorption spectrum are defined by the density or concentration of semiconductor charge carriers. A particular application of semiconductor optical thin films is their use as optical metasurfaces, which have features giving a lateral (this, is, in the plane of the film) modulation or variation of optical properties on the nanometre scale. This sub-wavelength patterning or nanostructuring interacts with incident light by resonance at optical wavelengths. The patterning can therefore be used to manipulate light, offering control over phase, polarisation, emission, reflection and absorption, for example. Optical metasurfaces are hence a promising replacement for bulk optical elements. A particular application, demonstrated using an aluminium-doped zinc oxide metasurface, is that of optical solar reflectors which can be used for radiative cooling of spacecraft and satellites [1]. Lateral modulation of the carrier concentration is also of interest in the fabrication of nano-optical circuits [2, 3].

Metal oxide semiconductors are attractive for use in optical and other applications, owing to a combination of high transparency at visible wavelengths and a high carrier density or concentration. To date, nanostructuring in these materials has typically been achieved by forming nanoscale physical structuring of a semiconductor layer, such as by a plasma etch or a lift-off approach to selectively remove unwanted portions of the semiconductor material and leave island-like features, or by controlled local deposition to form such features. The semiconductor carrier density in the layer is therefore modulated according to the physical presence or absence of the semiconductor material at any position. As a result, the optical metasurface has a non-planar surface which makes the addition of further layers or features over the optical metasurface, such antireflection coatings or electrical contacts, difficult. Also, the lack of flatness of the surface can lead to inferior optical performance owing to scattering from the multiple edges.

Group IV and group III-V semiconductor layers have been provided with lateral carrier density modulation by ion implantation or dopant diffusion applied through a mask defining the desired modulation pattern. These techniques can also be used with metal oxide semiconductors, but are substantially less effective because carrier concentration in these materials is substantially determined by defects, self-compensation and possibly hydrogen incorporation. Also, ion implantation is slow, costly and does not offer very precise control in metal oxides.

Furthermore, carrier concentration in metal oxides can be reduced if the metal oxide layer is grown or deposited in the presence of an oxygen plasma. This has been demonstrated in zinc oxide [4, 5]. The oxygen affects the defects and the hydrogen bonding. However, because this technique is carried out during deposition, the resulting layer has a uniform carrier density, lacking any lateral modulation. Conversely, carrier density increase has been shown in zinc oxide by deposition in the presence of a hydrogen plasma [6, 7]. In a similar approach, H₂O plasma treatment has been used in the fabrication of layers in thin film transistors [8], and fluorine plasma treatment to fill oxygen vacancies in a semiconductor is also known [9]. Oxygen plasma treatment in the fabrication of zinc oxide thin film transistors has been reported, where metal parts of the transistor structure shielded the zinc oxide layer from the oxygen plasma [10].

### SUMMARY OF THE INVENTION

Aspects and embodiments are set out in the appended claims.

According to a first aspect of certain embodiments described herein, there is provided a method of forming an optical thin film, comprising: providing an assembly comprising a layer of semiconductor material deposited on a substrate, the semiconductor material comprising a compound of at least one metal and a group VI element; depositing a masking layer onto the layer of semiconductor material, the masking layer being patterned to expose one or more regions of the layer of semiconductor material; applying to the assembly a plasma of the group VI element in order to cause indiffusion of the group VI element into the semiconductor material in the exposed regions while the masking layer blocks indiffusion in unexposed regions, the indiffusion causing a reduction in carrier density in the semiconductor material; and removing the masking layer; thereby forming, from the layer of semiconductor material, an optical thin film having a variation in carrier density and corresponding variation in optical properties matching the patterning of the masking layer in a plane parallel to the substrate.

According to a second aspect of certain embodiments described herein, there is provided an optical thin film formed according to the method of the first aspect.

The method of the first aspect may further comprise the deposition or other formation of one or more additional uniform or patterned layers of material over the optical thin film in order to produce an optical element or optical device. For example, the masking layer may be patterned in order to form an optical thin film with a first plasmonic resonant frequency, and the one or more additional layers may comprise a patterned layer of metallic material having a second plasmonic resonant frequency different from the first plasmonic resonant frequency, to produce an optical element with dual plasmonic resonance. In other examples, the one or more additional layers may comprise an antireflection coating. In such cases, a third aspect of certain embodiment described herein is directed to an optical element or an optical device formed according to these examples, or comprising an optical thin film according to the second aspect.

According to a fourth aspect of certain embodiments described herein, there is provided an optical solar reflector comprising an optical thin film formed according to the method of the first aspect.

These and further aspects of certain embodiments are set out in the appended independent and dependent claims. It will be appreciated that features of the dependent claims may be combined with each other and features of the independent claims in combinations other than those explicitly set out in the claims. Furthermore, the approach described herein is not restricted to specific embodiments such as set out below, but includes and contemplates any appropriate combinations of features presented herein. For example, optical thin films and fabrication techniques therefor may be provided in accordance with approaches described herein which includes any one or more of the various features described below as appropriate.

### BRIEF DESCRIPTION OF THE DRAWINGS

For a better understanding of the invention and to show how the same may be carried into effect reference is now made by way of example to the accompanying drawings in which:

FIG. 1 shows a schematic representation of steps in a method of forming an optical thin film according to a known method;

FIG. 2 shows a schematic representation of steps in a method of forming an optical thin film according to an example of a method as described herein;

FIG. 3 shows a flow chart of steps in a method of forming an optical thin film according to an example of a method as described herein;

FIG. 4A shows a scanning electron microscopy image and an atomic force microscopy measurement of an optical thin film formed according to a method as described herein;

FIG. 4B shows a scanning electron microscopy image and an atomic force microscopy measurement of an optical thin film formed according to the known method of FIG. 1;

FIGS. 5A and 5B show graphs of measured semiconductor carrier concentrations for AZO films with different aluminium levels in unpatterned form and patterned according to an example of a method as described herein, on logarithmic and linear scales respectively;

FIG. 6A shows a graph of measured optical absorption spectra of AZO films in unpatterned form, patterned according to an example of a method as described herein and patterned according to the FIG. 1 method;

FIG. 6B shows a graph of computer modelled optical absorption spectra for AZO films corresponding to the AZO films of FIG. 6A;

FIG. 7A shows a schematic cross-sectional side view of an example optical device including an optical thin film formed according to an example of a method described herein; and

FIG. 7B shows a scanning electron microscopy image of the upper surface of an optical device configured in line with the FIG. 7A example.

### DETAILED DESCRIPTION

Aspects and features of certain examples and embodiments are discussed/described herein. Some aspects and features of certain examples and embodiments may be implemented conventionally and these are not discussed/described in detail in the interests of brevity. It will thus be appreciated that aspects and features of optical thin films and methods discussed herein which are not described in detail may be implemented in accordance with any conventional techniques for implementing such aspects and features.

Optical thin films can be formed from semiconductor materials which are compounds of metals and elements from group VI of the periodic table. The group VI elements include oxygen, sulphur, selenium and tellerium. While the group as a whole is referred to as the chalcogens, oxygen is often discussed separately. Hence, the semiconductor compounds may be designated as metal oxides when comprising a compound of metal and oxygen, and as metal chalcogenides when comprising a compound of metal and one of sulphur, selenium and tellerium. However, the term metal chalcogenide can be considered to include metal oxides. The terms may be used interchangeably herein to indicate compounds of metals and group VI elements, unless it is clear from the context that only oxides or only non-oxides are being referred to.

Additionally, these semiconductor materials may comprises one or more dopants. Examples of useful dopants include aluminium, boron, gallium, indium, titanium, zirconium and hafnium, although other elements are not excluded. Herein, the terms metal oxide and metal chalcogenide may be used to include both doped and undoped semiconductor materials. If the context requires, the presence or absence of dopants is specifically indicated. Undoped semiconductor compounds comprising a single metal and a group VI element can also be termed binaries.

Many metal chalcogenides, and in particular metal oxides, are particularly useful materials for optical thin films owing to being transparent at visible optical wavelengths. Semiconductors of this type can be categorised as transparent conducting oxides (TOO). Examples having dopants are indium tin oxide (ITO) and aluminium-doped zinc oxide (AZO). The concentration or density of charge carriers in the semiconductor material defines the optical properties of the material, such as refractive index, and metal chalcogenides can have high carrier concentrations, which adds to their usefulness. In order to provide a thin film which is able to operate as an optical metasurface, the carrier density (and correspondingly, the optical properties) can be patterned to provide plasmonic resonance at optical wavelengths. The modulation is in the plane of the thin film, so can be considered to be a lateral modulation or variation. The plane of the thin film occupies dimensions which are substantially orthogonal or perpendicular to the substrate or other underlying stratum or component of a device on which the thin film is laid or deposited. The size or lateral dimension of the patterned features is selected to achieve a desired frequency for the plasmonic resonance. Typically, features can be smaller than 100 nm for applications in the visible and ultraviolet parts of the spectrum, and conversely as large as 1 cm for radio-frequency applications. For applications where the thin film is intended to operate at near-infrared wavelengths, feature size could be in the range of 200 nm to 5000 nm. Patterning or modulation of the carrier density on other scales may also be useful, for other applications of thin films.

In metal oxides, the patterning is commonly carried out by plasma etching or lift-off techniques through a mask defining the desired pattern. This removes portions of the semiconductor material which are not protected by the mask. A converse approach is that of controlled local deposition of the semiconductor material into the desired pattern. All these techniques create physical island-like portions of the semiconductor material, so that in the lateral direction, the carrier density is modulated by being high where semiconductor is present, and zero where there is no semiconductor. The resulting surface of the semiconductor layer is not flat (non-planar), which has some disadvantages. Optical properties may be inferior owing to from the multiple edges and surfaces. Also, additional process steps that may be required to incorporate the semiconductor layer into a more complex optical element or device may be hindered or prevented altogether.

An alternative approach to tailoring the carrier density in metal oxides has been demonstrated, in which exposure to an oxygen plasma during deposition of a zinc oxide layer produced a reduction in the carrier density [4, 5]. However, the reduction is uniform across the layer since the plasma treatment takes place while the layer is being formed, so the technique is not useful for patterning or nanostructuring in the lateral direction.

In order to address these issues, the current disclosure presents an alternative method for forming optical thin films of metal oxide and metal chalcogenide semiconductors having lateral modulation of the charge carrier density. After formation of a layer of the semiconductor material on a substrate or other supporting structure or element, a masking layer or mask is laid down over the semiconductor material with a pattern corresponding to the desired pattern of carrier density modulation. The semiconductor is then exposed to a plasma of relevant group VI element comprised in the semiconductor compound for a specified period. It has been found that during this exposure, the plasma material diffuses into or penetrates the semiconductor, and this reduces the carrier density (and correspondingly changes the optical properties). The mask protects those portions of the semiconductor layer which lie under it, hence blocking the plasma exposure and indiffusion in these areas. The portions exposed through the mask experience the plasma treatment so that the carrier density is reduced. At the end of the plasma treatment, the mask is removed, to leave a planar semiconductor surface. The film has a variation of carrier concentration in the lateral direction, comprising regions of higher (unmodified) carrier density where the semiconductor has been protected by the mask, and regions of lower (modified) carrier density where the semiconductor has been exposed to the plasma. Hence, a transverse carrier density profile, with a pattern of high and low carrier densities corresponding to the masking layer, can be formed in the semiconductor in a controlled manner.

FIG. 1 shows schematic representations of steps in an example known method for forming lateral carrier density modulation in a layer of semiconductor.

FIG. 1A shows an assembly 10 comprising a substrate 1 onto which a layer (for example a thin film) of a metal oxide semiconductor 2 has been formed, by any known deposition technique. The semiconductor 2 is a transparent conducting oxide (TCO) having a relatively high (H) density of charge carriers, so is labelled as H-TCO. A mask 3 is formed over the semiconductor 2, of a type which is suitable for performing plasma etching. Plasma etching is an established technique which will be understood by the skilled person. The mask 3 is a discontinuous layer over the semiconductor 2, having a patterned distribution corresponding to desired lateral profile for the carrier density in the semiconductor 2.

FIG. 1B shows the assembly 10 after the plasma etching has been carried out. The presence of the mask 3 protects the semiconductor 2 from the plasma applied during the etch. However, in the spaces of the mask 3, the semiconductor 2 is exposed to the plasma, and is etched away, in this case as far down as the surface of the substrate 1. Hence, the semiconductor 2 assumes the same discontinuous lateral distribution as the mask 3.

FIG. 10 shows the assembly 10 after a next step, in which the material of the mask layer is removed. This leaves the assembly comprising only the substrate 1, supporting the remaining portions of the semiconductor layer 2 which were protected by the mask 3 and therefore not removed by the etching. The semiconductor 2 therefore comprises a plurality of “lands” of semiconductor material interspersed with “pits” where the semiconductor material is absent. This gives a corresponding lateral carrier density profile comprises high carrier density parts where the material is present, interspersed with zero carrier density parts where the material is absent. As can be appreciated, the upper surface of the assembly 10, defined by the semiconductor surface 2, is nonplanar, in other words is not flat, owing to the removal of material by the etching process.

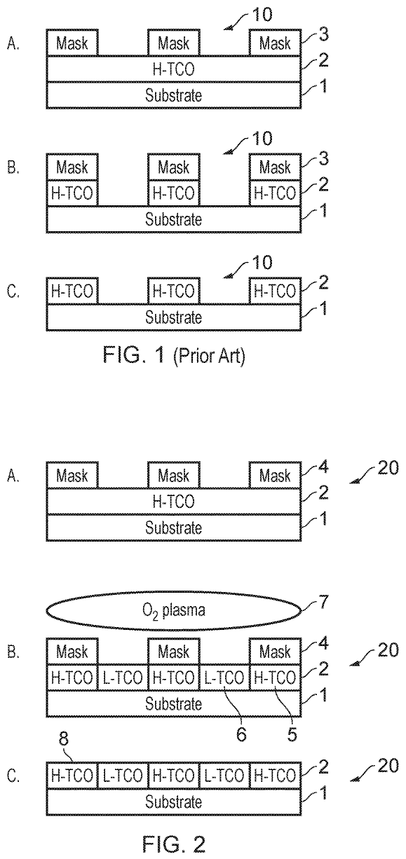

FIG. 2 shows schematic representations of steps in an embodiment of a method according to the present disclosure.

FIG. 2A shows an assembly 20. The assembly 20 comprises a planar substrate 1, which supports a continuous layer of semiconductor material 2. The semiconductor material 2 can be deposited onto the substrate by any method as preferred or convenient, for example by sputtering, or any physical or chemical vapour deposition method. The semiconductor 2 is a compound of at least one metal and a group VI element where in this example the group VI element is oxygen so that the semiconductor is a metal oxide, with or without a dopant. For example, the semiconductor layer 2 may comprise aluminium-doped zinc oxide (AZO), an example of a transparent conducting oxide (TCO). The semiconductor has a carrier density which is relatively high to provide a particular level of optical properties, indicated as H-TCO.

The semiconductor layer 2 may have a thickness in the range of about 5 nm to 1000 nm, depending on the intended application. For applications described in detail herein, typical thicknesses of between 50 nm and 200 nm may be useful. However, the invention is not limited in this regard, and other thicknesses may be used.

A masking layer or mask 4 is deposited or otherwise formed onto the layer of semiconductor material 2. The masking layer 4 is a discontinuous layer patterned according to a desired distribution in the lateral direction (that is, in the plane of the semiconductor layer, and parallel to the plane of the substrate) of the carrier density in the semiconductor 2. Areas or regions of the semiconductor layer 2 which are to retain the high carrier density (H) are covered by the masking layer 4, so as to be unexposed, while areas or regions of the semiconductor layer 2 in which a lower carrier density (L) which is less than the high carrier density) are not covered by the masking layer 4, so as to be exposed.

In this example, the masking layer 4 is formed as a so-called “hard mask”, the purpose of which is to protect the underlying, unexposed, portions of semiconductor from a plasma to which the assembly is exposed in a subsequent stage. The hard mask 3 is able to block the plasma material from diffusing into the semiconductor 2. The hard mask 3 is able to wholly or substantially prevent or inhibit such diffusion, so that the carrier concentration in the semiconductor 2 is not affected to any significant degree. For example, the mask may block the plasma such that a ratio of the carrier density in the exposed regions and the unexposed regions of the underlying semiconductor material (so, the ratio low to high, or L:H) is achieved which is at least 1:2 (that is, the plasma treatment reduces the carrier density to about a half of its “high” value) and possibly up to or above 1:100 (so that the plasma treatment reduces the carrier density to about one hundredth or less of the original “high” value). The useful variation or difference in absolute carrier concentration or density between the exposed and unexposed underlying semiconductor layer will depend on the intended resonant frequency of the application for which the semiconductor is designed.

An example of a suitable mask material to implement a hard mask is silicon nitride, SiN. Any other material which is able to provide an appropriate barrier to protect the semiconductor from indiffusion of the plasma can be used. For example, various metals can be used if preferred. An example of a suitable metal is gold. Other hard mask materials will be known to the skilled person, and are not precluded.

The mask layer 43 can be patterned by any suitable or convenient technique; the invention is not limited in this regard. For example, a SiN hard mask might have a pattern which is defined using an ultraviolet or e-beam resist “soft mask” which is fabricated by exposure of a layer of mask material to light or electron beams to remove unwanted portions of the material and thereby pattern the mask. It may also be possible by careful choice of soft mask resist material and exposure parameters to form a soft mask that can itself act directly as the diffusion barrier masking layer 4, so that a hard mask is not required.

The barrier-providing functionality of the mask layer 4 may depend also on its thickness as well as the material from which it is made. The mask layer 4 should have a thickness adequate to provide the required zero or minimal diffusion of the plasma material into the semiconductor material. In order to save material, and reduce deposition time for the mask layer, a minimal mask thickness may be employed. For example, the mask may have a thickness of about 20 nm; this can provide adequate functionality as a diffusion barrier. Thinner masks may also be usable, such as in the range of 10 nm to 20 nm. However, in order to enable good process control (ensuring that the mask is thick enough in all places for proper blocking, for example), a greater thickness may be preferred. For example, the mask may have a thickness in the range of about 60 nm to 80 nm. Other thicknesses are not excluded, however, for example in the range of 50 nm to 70 nm, or 70 nm to 90 nm, or 50 nm to 90 nm, or even significantly thicker, such as overall, in the range of 20 nm to 80 nm, or 10 nm to 500 nm.

FIG. 2B shows a next stage in the method, in which a plasma treatment is applied to the assembly 20. The semiconductor layer 2, through the masking layer 4, is exposed to a plasma. The purpose of the plasma exposure is to modify the carrier density in the semiconductor material, which occurs when the plasma material diffuses into the semiconductor. In a metal-group VI semiconductor, the origin of the charge carriers is still a matter of some conjecture, but is usually attributed mainly to either vacancies of the group VI element or to hydrogen content. The addition of more of the group VI element reduces the vacancy level, or reduces the hydrogen content, both of which act to reduce the charge carrier concentration. This reduces the electrical resistivity of the semiconductor material, and produces a corresponding change in optical properties arising from the charge carrier presence.

It has been found that the group VI element can be introduced by indiffusion into the semiconductor material, if the semiconductor material is exposed to a plasma of the group VI element after the semiconductor layer has been deposited (in contrast to previous techniques of plasma treatment during deposition). This allows lateral spatially selective modification of the carrier concentration if a mask layer is applied over the semiconductor layer in order to allow the plasma to reach certain areas of the semiconductor material while blocking other areas from the plasma exposure.

In the present example, the semiconductor material is AZO, in other words, a metal oxide semiconductor. Therefore, the plasma used is an oxygen plasma. In this example a plasma of molecular oxygen, O₂, is used, but it is also possible to use a plasma of ozone, O₃, or a plasma of water, H₂O. If the semiconductor material comprises another chalcogen, and not oxygen, the plasma should comprise the relevant element, such as in a molecular form or as a dihydrogen monochalcogen. Hence, the plasma may by a plasma of sulphur, selenium or tellerium, to match the group VI element in the semiconductor.

So, FIG. 2B shows an O₂ plasma 7 applied to the assembly 20, so that regions 6 of the semiconductor layer 2 which are exposed by the mask 4 and therefore unprotected, are exposed to the oxygen which therefore diffuses into the semiconductor material to reduce the carrier density in those regions. The regions 5 of the semiconductor layer 2 under the material of the mask 4 are protected from the oxygen because the mask blocks all or most of the oxygen from being able to diffuse into the semiconductor 2. The carrier density in these regions 5 is therefore unchanged or largely unchanged. At the end of the plasma exposure, the semiconductor layer 2 therefore comprises a lateral profile of regions 5 of high carrier density (H-TCO) interspersed with regions 6 of lower carrier density (L-TCO), reduced from the high level by the oxygen indiffusion.

The plasma may be generated and applied using any known technique. As an example, an inductive coupled plasma (ICP) generator can be used. This is an attractive technique because it does not include ion bombardment present which is present in some plasma generation and which can cause physical damage to the semiconductor material.

The plasma exposure is usefully performed at an elevated temperature, that is, a temperature above room temperature. This has been found to aid the diffusion of the plasma material into the semiconductor material. The temperature can be achieved by placing the assembly 20 and the plasma generation system in an oven, for example, or by mounting the assembly 20 on a heating element to provide direct heating of the assembly 20. Temperatures in the range of about 80° C. to 320° C. might be used, for example. More particularly, the temperature may be in the range of about 100° C. to 300° C., such as a temperature of about 120° C. (or in the range of 100° C. to 140° C. or 110° C. to 130° C.) or about 225° C. (or in the range of about 205° C. to 245° C. or 215° C. to 235° C.). Higher temperatures have been found to be useful in some cases, and may, for example, enable a reduced plasma exposure time. The temperature may be at or around 300° C., for example, such as in the range of 280° C. to 320° C., or 290° C. to 310° C. Temperatures in excess of 320° C. are not excluded, however. The temperature may be chosen having regard to the particular combination of semiconductor material, desired plasma exposure time, and mask material properties. For example, a temperature of about 300° C. has been found to be useful for O₂ plasma exposure of AZO through a SiN mask, as in the present example, for a mask thickness in the range of about 60 nm to 80 nm, and a plasma treatment time of about 20 minutes. The parameters may be adjusted to achieve the desired reduction in carrier concentration by providing the appropriate amount of plasma material diffusion into the semiconductor material.

The temperature may be to some extent constrained by the choice of material for the masking layer 4. A hard mask material such as SiN is well able to withstand temperatures up to and above 300° C., while a metallic masks such as gold may require a much lower temperature, such as 100° C. or below, in order to avoid or reduce damage to the mask.

Similarly, the plasma treatment time or exposure time can also be selected in order to obtain a particular reduced carrier concentration in the exposed regions of the semiconductor material. Indeed, if other parameters are fixed, such as by physical characteristics of the system and other fabrication steps, selection of the time can be a convenient and simple way to tailor the carrier concentration. The exposure time may be up to 20 minutes, or up to 30 minutes, or up to 40 minutes, or up to 50 minutes, or up to 60 minutes, for example. Longer or shorter times are not excluded, however. Exposures of around 20 minutes are possible, which may be considered useful as being shorter and hence reducing the overall fabrication time. For example, the exposure may be in the range of 15 minutes to 25 minutes, or 17 minutes to 23 minutes, or 20 minutes. A 20 minute exposure of a AZO semiconductor layer with a SiN mask to an O₂ plasma at a temperature of 300° C. has been found to be effective, for example.

FIG. 2C shows the assembly 20 post-plasma treatment, and also following removal of the masking layer 4. This can be done by any known mask removal technique appropriate to the mask material, as will be apparent to the skilled person. Importantly, the mask can be removed with little or no damage to the semiconductor layer 4, so that the semiconductor layer 4 has a flat, planar upper surface 8, substantially the same as the original surface of the as-deposited semiconductor layer. A planar surface of this kind is wholly suitable for any subsequent process steps that involve the addition of one or more further layers or features over the semiconductor. Examples include antireflection coatings and additional optical metasurfaces. Additionally, the surface itself can provide a good optical performance for the semiconductor layer, in that scattering is reduced.

These qualities should be contrasted with the non-planar surface produced by the technique described with respect to FIG. 1. While planarization techniques exist in the semiconductor industry, these are difficult and costly, and typically will lead to distorted optical properties of the semiconductor layer.

Furthermore, the FIG. 1 approach only allows the lateral charge carrier profile to include the high charge carrier density and a zero charge carrier density. The FIG. 2 approach allows the profile to comprise the high charge carrier density and a lower charge carrier density which can be tailored as required by appropriate selection of the operational parameters.

Hence, the ability of the FIG. 2 procedure to enable formation of a planar semiconductor thin film layer with a customisable lateral carrier density profile (and therefore also a customisable lateral modulation of optical properties) offers a range of enhancements compared to previously used methods.

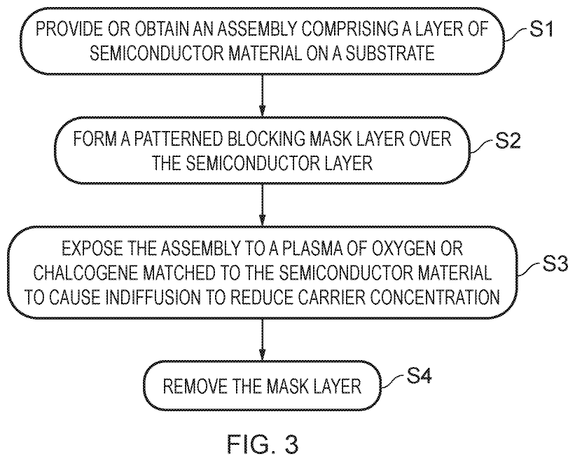

FIG. 3 shows a flow chart summarising the various stages described above. In a first step S1, an assembly is provided or otherwise obtained. This includes both fabricating the assembly as part of the procedure, or obtaining a pre-fabricated assembly from an external source or a previously fabricated stock. The assembly comprises a thin film layer of a semiconductor material comprising a compound of one or more metals with a group VI element, deposited or otherwise formed or laid down onto a substrate. The substrate may be any suitable supporting layer, typically planar, and includes a direct substrate layer onto which the semiconductor material is deposited, and also more complex supporting structures including additional layers under the semiconductor, for example if the semiconductor layer is to be an upper layer in a multi-layer device.

In a second step S2, a patterned hard mask is formed over the semiconductor layer, with a pattern corresponding to a desired lateral profile of carrier density in the semiconductor layer.

In a third step S3, the assembly is exposed to a plasma of the group VI element, for example an oxygen plasma when the semiconductor is a metal oxide. This exposure allows diffusion of the group VI element into the semiconductor in the regions not covered by the mask, causing a reduction in carrier concentration in those regions. The regions under the mask are protected from the indiffusion and hence retain a carrier concentration at or close to the original level.

In a fourth step S4, the mask layer is removed to restore the planer surface of the semiconductor layer, which now has lateral variation or modulation of carrier density and correspondingly of optical properties formed within it, owing to the diffusion.

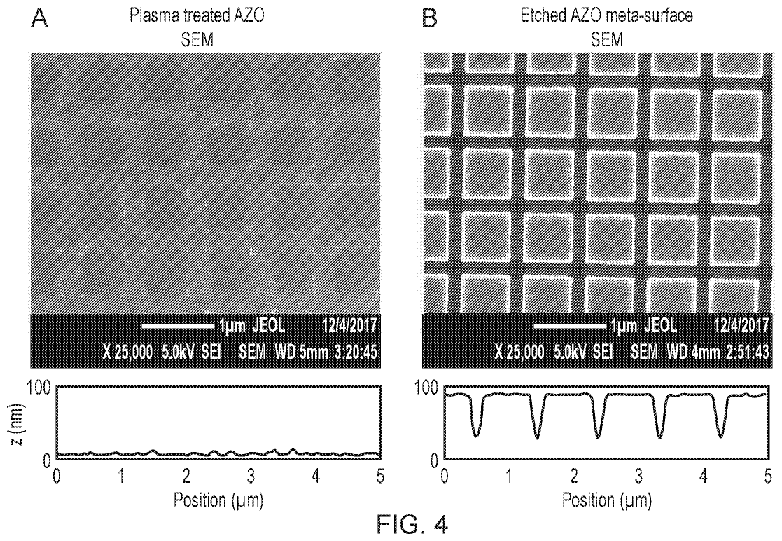

FIGS. 4A and 4B show microscopy images and measurements demonstrating the nature of the semiconductor surface obtained by the proposed method.

FIG. 4A shows results from an AZO thin film with a lateral charge carrier density profile modulated using a method in line with the FIG. 2 technique, and therefore having a physical structure like that shown in FIG. 2C. The upper image in FIG. 4A is a scanning electron microscope (SEM) image of the AZO film, in plan view. From this the modulated carrier profile density can be observed, having a generally grid-shaped pattern. Note the relatively low contrast in the image, indicative of a flat surface.

The lower image in FIG. 4A is an atomic force microscopy (AFM) image of the same AZO thin film layer, in cross-section through the film (perpendicular to the plan view image of FIG. 4A). The high degree of flatness of the semiconductor surface can be appreciated; the height of the surface varies by only a few nanometres (less than 10 nm) laterally across the semiconductor layer.

FIG. 4B shows results from an AZO thin film patterned using a plasma etch technique like that described with respect to FIG. 1, and therefore having a physical structure like that shown in FIG. 1C. The upper image in FIG. 4B is an SEM image of the AZO film in plan view. Again, a generally grid-shaped pattern has been applied to the semiconductor. However, the image has much greater contrast than that of FIG. 4A, indicating different depths and surface angles in the thin film.

The lower image in FIG. 4B is an AFM image of the same AZO thin film layer, in cross-section through the film. The highly non-planar nature of the surface is immediately apparent. The surface comprises a series of lands with intervening pits where the semiconductor material has been etched away. The depth of the pits is greater than 50 nm, making the surface significantly less flat than the example in FIG. 4A.

Despite the very different physical structures of the two semiconductor thin film layers shown in FIGS. 4A and 4B, the planar film of FIG. 4A can show a same or similar optical response to a non-planar film such as that of FIG. 4B. Results are presented below to demonstrate this.

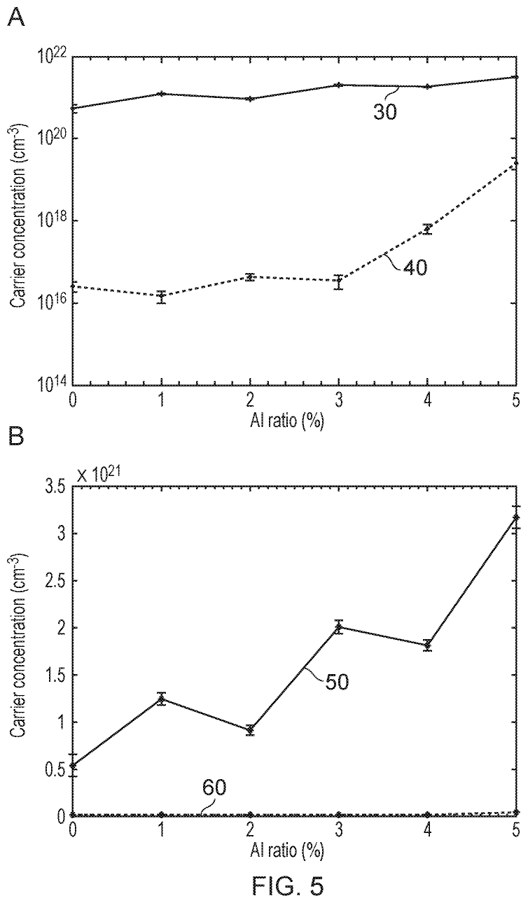

FIGS. 5A and 5B shows graphs of measured carrier concentration (carrier density) demonstrating the reduction in carrier concentration that can be achieved by plasma exposure as described herein. Semiconductor thin films of AZO were prepared having different levels or ratios of aluminium doping, ranging from 0% (undoped) to 4% aluminium. Each film was exposed to oxygen plasma for a 20 minute exposure time at a plasma exposure temperature of 300° C.

FIG. 5A shows a graph of the measured carrier concentration (vertical axis) for the AZO thin film samples having different aluminium ratios. The carrier concentration data is plotted on a logarithmic scale. The carrier concentration was measured via the Hall effect in the conventional manner for determining DC carrier concentration in a semiconductor. The line 30 shows the carrier concentrations for the samples before exposure to the oxygen plasma, which therefore had carrier density at a “high” level. As can be seen, all samples have a carrier concentration well in excess of 10²⁰ cm⁻³, generally around 2×10²⁰ cm⁻³.

Line 40 in FIG. 5A shows the measured carrier concentrations for the same samples after oxygen plasma treatment. In all cases, the carrier concentration has been substantially reduced by the oxygen diffusion, giving a corresponding decrease in optical properties and optical response. It appears that the 0% aluminium sample (that is, pure ZnO) undergoes the largest decrease so may seem preferable, but in fact all samples have had their carrier concentration reduced below 5×10¹⁹ cm⁻³ so in effect will act as an insulator as far as their optical properties at the intended wavelengths are concerned.

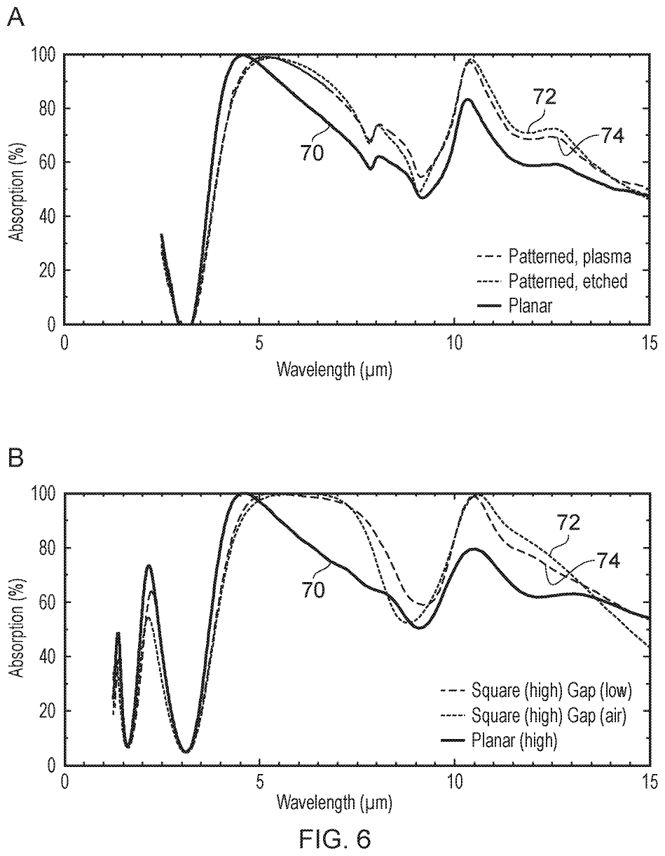

FIG. 5B shows a further graph of carrier concentration, which allows this point to be appreciated more readily. The same data is plotted as in FIG. 5A, but with a linear scale on the vertical axis for the carrier concentration. Line 50 shows the carrier concentrations for the AZO samples before plasma exposure, indicating that the carrier concentrations are generally in the optically useful range of greater than 5×10¹⁹ cm⁻³, with an increasing concentration for larger aluminium ratios. FIG. 6 shows the data for the samples after the oxygen plasma exposure, and effectively lies at the zero level on the linear scale, giving a more useful visual demonstration that the usable optical characteristics of the AZO have been removed for all the samples, regardless of aluminium doping level.

These results demonstrate how the plasma treatment proposed herein can be used as a substitute for the plasma etching and similar processes which are currently used to form metal-group VI semiconductors into optical metasurfaces and other components. An appropriate amount of indiffusion achieve by exposure to the plasma reduces the carrier concentration below an optically-effective level, having the same effect as the physical removal of the semiconductor material, which corresponds to a carrier concentration of zero.

FIG. 6A shows a graph of experimental results which support the above assertion. The graph shows measurements made of the variation of optical absorption (as a percentage, vertical axis) with incident optical wavelength (horizontal axis) for various AZO thin films. The lowest curve, labelled 70, is for a planar AZO film with its inherent carrier density, at a “high” level giving measurable optical properties. Two other curves are shown. Curve 72 (dashed line) is the corresponding absorption spectrum measured for an AZO film that was patterned as an optical metasurface using a conventional plasma etch (FIG. 1). The remaining curve 74 is the corresponding absorption spectrum measured for an AZO film patterned as an optical metasurface using an oxygen plasma exposure according to present proposal. It can be seen that the curves 72 and 74 are very closely matched, indicating that the new method is able to produce optical thin films with the same optical properties as the known methods. Note also the difference in the spectra for the unpatterned thin film and the patterned metasurface thin films. The absorption is increased at all wavelengths above 5 μm.

FIG. 6B shows corresponding data to that of FIG. 6A, but obtained via computer modelling. Comparison with FIG. 6A shows good agreement between simulation and experiment.

Optical thin films of semiconductor material patterned using the described plasma exposure technique can be used as they stand, but may also be integrated into more complex devices and components by the addition or inclusion of one or more further layers. The layers may be included under the semiconductor layer, as part of the “substrate” supporting the semiconductor, or may be added over the semiconductor layer after it is patterned, or both.

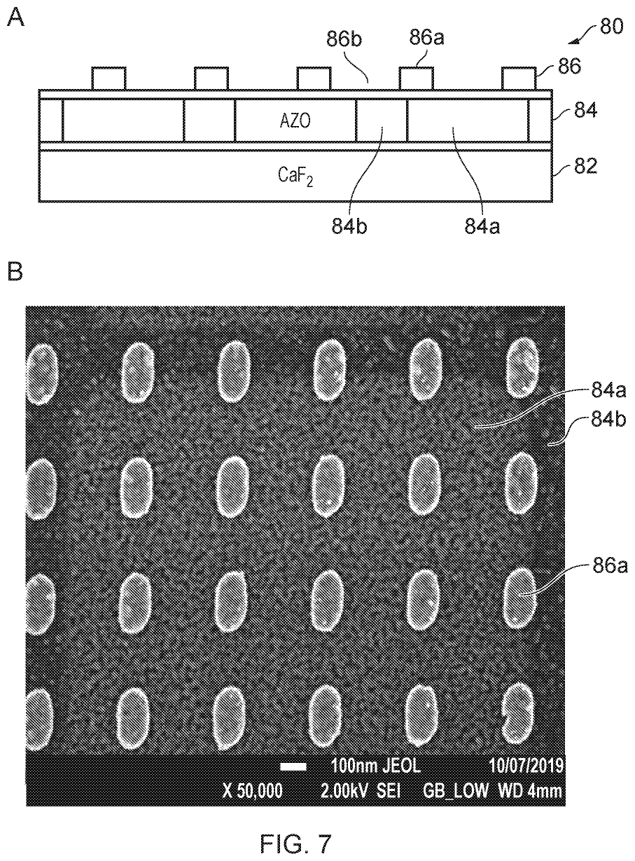

FIG. 7A shows a schematic cross-sectional view of an example of such a device. In this case, the device is a dual plasmonic resonance structure, comprising two optical metasurfaces tuned for resonance at different optical wavelengths and therefore offering a combined optical response to incident light. The device 80 comprises a calcium fluoride substrate 82 which supports an AZO thin film 84 (continuous layer of semiconductor) which has been patterned by oxygen plasma exposure to comprise a lateral modulation of carrier concentration, with regions of high concentration 84A, and regions of lower concentration 84B reduced by indiffusion of oxygen during the plasma exposure. Overlying the AZO layer is a further optical metasurface comprising a discontinuous layer of gold. This has been patterned by a plasma etch to remove portions of the gold, leaving lands 86a having a high carrier concentration alternating with pits 86b where the gold has been etched away to give zero carrier concentration. The topologically flat upper surface of the AZO layer allows the gold layer to be more easily formed without edge effects or the need for specific alignment with features of the underlying AZO layer. The features of the gold layer are smaller than the regions in the AZO layer, in order to provide different resonant frequencies.

FIG. 7B shows a SEM image top plan view of a part of an actual device structured according to the FIG. 7A schematic. The larger scale of the features 84a, 84b in the AZO layer is apparent in the regions depicted in the darker shades, while the small gold lands 86a can be seen as overlying the AZO pattern. The AZO features have a dimension of 1850 nm to give an optical response at infrared wavelengths, while the gold features have dimensions of 100 nm to give an optical response at visible and ultraviolet wavelengths.

In summary, the method described herein for forming optical thin films, such as optical metasurfaces, comprises a masked exposure of semiconducting metal chalcogenides (including oxides) to a chalcogenide plasma (including oxygen) to create a lateral carrier density modulation or profile in the semiconductor without any topographical change to the semiconductor layer. The planar surface offers both improved optical and mechanical properties of the film, as well as facilitating any subsequent fabrication steps for integrate the film into optical and optoelectronic devices.

Such devices and thin films have a variety of applications. An example is as optical solar reflectors (OSR) for satellite cooling control; the thin films may be patterned as metasurfaces and applied as coatings. It is expected that metal oxide metasurfaces for OSRs can be fabricated in larger sizes than is possible for conventional quartz OSRs currently used in the satellite industry.

The various embodiments described herein are presented only to assist in understanding and teaching the claimed features. These embodiments are provided as a representative sample of embodiments only, and are not exhaustive and/or exclusive. It is to be understood that advantages, embodiments, examples, functions, features, structures, and/or other aspects described herein are not to be considered limitations on the scope of the invention as defined by the claims or limitations on equivalents to the claims, and that other embodiments may be utilised and modifications may be made without departing from the scope of the claimed invention. Various embodiments of the invention may suitably comprise, consist of, or consist essentially of, appropriate combinations of the disclosed elements, components, features, parts, steps, means, etc., other than those specifically described herein. In addition, this disclosure may include other inventions not presently claimed, but which may be claimed in the future.

### REFERENCES

[1] Sun et al, “Metasurface optical solar reflectors using AZO transparent conducting oxides for radiative cooling of spacecraft”, ACS Photonics, 5, 495-501, 2018
[2] Gui et al, “Towards integrated metatronics: a holistic approach on precise optical and electrical properties of indium tin oxide”, Scientific Reports, 9, 11279, 2019
[3] Engheta, “Circuits with light at nanoscales: optical nanocircuits inspired by metamaterials”, Science, 317, 1698, 2007
[4] Thomas et al, “Highly tunable electrical properties in undoped ZnO grown by plasma enhanced thermal-atomic layer deposition”, ACS Applied Materials & Interfaces, 4, 3122-3128, 2012
[5] Huang et al, “Fermi level tuning of ZnO films through supercycled atomic layer deposition”, Nanoscale Research Letters, 12, 514, 2017
[6] Macco et al, “Atomic layer deposition of high-mobility hydrogen-doped zinc oxide”, Solar Energy Materials and Solar Cells, 172, 111-119, 2017
[7] Wang et al, “Effects of H₂ plasma treatment on properties of ZnO:Al thin films prepared by RF magnetron sputtering”, Surface & Coatings Techn. 205, 5269, 2011
[8] TW 365033
[9] CN 108475620 and WO 2017/123552
[10] Lee et al, “The effect of oxygen remote plasma treatment on ZnO TFTs fabricated by atomic layer deposition”, Physica Status Solidi A, 207, 1845, 2010

1. A method of forming an optical thin film, comprising:
providing an assembly comprising a layer of semiconductor material deposited on a substrate, the semiconductor material comprising a compound of at least one metal and a group VI element;
depositing a masking layer onto the layer of semiconductor material, the masking layer being patterned to expose one or more regions of the layer of semiconductor material;
applying to the assembly a plasma of the group VI element in order to cause indiffusion of the group VI element into the semiconductor material in the exposed regions while the masking layer blocks indiffusion in unexposed regions, the indiffusion causing a reduction in carrier density in the semiconductor material; and
removing the masking layer;
thereby forming, from the layer of semiconductor material, an optical thin film having a variation in carrier density and corresponding variation in optical properties matching the patterning of the masking layer in a plane parallel to the substrate.

2. A method according to claim 1, in which the semiconductor material is a metal-oxide compound.

3. A method according to claim 2, in which the metal-oxide compound is a transparent conducting oxide.

4. A method according to claim 1, in which the group VI element is one of sulphur, selenium or tellerium.

5. A method according to claim 2, in which the semiconductor material includes a metallic element as a dopant.

6. A method according to claim 5, in which the semiconductor material is aluminium-doped zinc oxide or indium-doped tin oxide.

7. A method according to claim 5, in which the dopant comprises aluminium, boron, gallium, indium, titanium, zirconium or hafnium.

8. A method according to claim 2, in which the plasma is an oxygen plasma of molecular oxygen or ozone or water.

9. A method according to claim 1, in which the masking layer is formed from a hard mask material.

10. A method according to claim 9, in which the hard mask material comprises silicon nitride.

11. A method according to claim 9, in which the hard mask material comprises a metallic material.

12. A method according to claim 1, in which the masking layer has a thickness of 20 nm or greater.

13. A method according to claim 12, in which the masking layer has a thickness in the range of 60 to 80 nm.

14. A method according to claim 1, in which the plasma is applied for a duration up to 40 minutes.

15. A method according to claim 14, in which the plasma is applied fora duration in the range of 15 to 25 minutes.

16. A method according to claim 14, in which the plasma is applied for a duration of 20 minutes or longer.

17. A method according to claim 1, in which the plasma is applied while the semiconductor material is heated to a temperature in the range of 80° C. to 320° C.

18. A method according to claim 18, in which the semiconductor material is heated to a temperature in the range of 280° C. to 320° C.

19. A method according to claim 1, in which, after removal of the masking layer, the optical thin film has a substantially planar surface.

20. A method according to claim 1, further comprising the deposition or other formation of one or more additional uniform or patterned layers of material over the optical thin film in order to produce an optical element or optical device.

21. A method according to claim 20, in which the masking layer is patterned in order to form an optical thin film with a first plasmonic resonant frequency, and the one or more additional layers comprises a patterned layer of metallic material having a second plasmonic resonant frequency different from the first plasmonic resonant frequency, to produce an optical element with dual plasmonic resonance.

22. A method according to claim 20, in which the one or more additional layers comprises an antireflection coating.

23. An optical thin film formed according to the method of claim 1.

24. An optical element or optical device formed according to the method of claim 20.

25. An optical solar reflector comprising an optical thin film formed according to the method of claim 1.
